(19) United States
(12) Patent Application Publication
(10) Pub. No.: US 2014/0104777 A1
(43) Pub. Date: Apr. 17, 2014

(54) RAIL ADAPTER FOR TOOL-LESS COUPLING TO A RACK

(71) Applicant: DELL PRODUCTS L.P., Round Rock, TX (US)

(72) Inventor: Gregory L. Henderson, Round Rock, TX (US)

(73) Assignee: DELL PRODUCTS L.P., Round Rock, TX (US)

(21) Appl. No.: 13/654,063

(22) Filed: Oct. 17, 2012

(51) Int. Cl. H05K 7/14; F16B 7/00; F16B 17/00; G06F 1/16; B23P 11/00

(52) U.S. Cl. 361/679.31; 29/525.01; 403/345; 403/376

(57) ABSTRACT

An adapter couples to a rail for tool-less mounting of the rail to a rack, such as a rack for holding information handling systems. The adapter has a pin that fits though an opening at a front face of the rail and a support that couples to the pin from the rear face of the rail. The support has a shape for insertion into an unthreaded rack opening. If a rack has threaded openings, the adapter is removed to insert a threaded screw through the opening at the front face and into the threaded opening to secure the rail to the rack.

### BACKGROUND OF THE INVENTION

1. Field of the Invention

The present invention relates in general to the field of information handling system rail-to-rack coupling devices, and more particularly to an information handling system rail adapter for tool-less coupling to a rack.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems are often disposed vertically-stacked in racks of a data center. A typical rack has plural vertically-defined slots with opposing rails that slide information handling systems into and out of the rack interior. Generally, each rack slot has a standardized dimension based upon a rack unit, known as a U. Each standardized rack unit is 1.75 inches in height with a typical full size rack having 44U, which amounts to roughly six feet of height for storing equipment.

Rack structures typically have vertically disposed openings along opposing sides that accept rails that in turn support information handling systems. The vertically disposed openings generally have a standardized configuration for accepting coupling devices, such as coupling devices that secure a rail to the rack structure. Standardized openings include standardized round and square openings that do not have threads, and standardized round threaded openings. Unthreaded openings accept an unthreaded square or round peg to support the rail's weight within the rack without attaching the rail to the rack. Threaded openings accept a standard pan head screw that couples the rail to the rack.

One convenient tool for attaching a rail to a rack is provided by “Tool-less Rack Mounting Apparatus and Systems” U.S. patent application Ser. No. 12/367,687, by Gregory Lane Henderson, which is incorporated herein as if fully set forth. A support extends from the rail with a round portion and a square portion, each sized to fit in a standardized rack opening. If the rack has round openings, the round portion supports the rail in the rack. If the rack has square openings, the round portion fits completely through the square opening so that the square portion supports the rail in the rack. An attachment device operable from the exposed portion of the rail engages with an opening of the rack to attach the rail to the rack.

Tool-less attachment of a rail to a rack with an attachment device operable from the exposed portion of the rail provides convenient access by an end user to the rail. For instance, in a rack that has multiple vertically stacked 1U information handling systems, minimal space is available for an end user to work on a rail, such as coupling or decoupling a rail to a rack. The tool-less attachment device provided by Henderson allows an end user to quickly and easily snap a rail into place on a rack. However, one difficulty with the tool-less attachment device of Henderson is that an adapter is generally needed if a rack has standardized threaded round openings. Rack adapters are typically ordered and sent separately from rails so that a misplacement or incorrect order of rack adapters can delay installation of new information handling systems. The rack adapters cause the rail to sit forward in the rack by approximately ¾ of an inch, which can sometimes interfere with the front door of the rack.

### SUMMARY OF THE INVENTION

Therefore a need has arisen for a system and method which attaches to threaded and unthreaded openings of an information handling system rack.

In accordance with the present invention, a system and method are provided which substantially reduce the disadvantages and problems associated with previous methods and systems for attaching a rail to an information handling system rack. An adapter couples to the rail with openings of the rail otherwise used for threaded screws to pass to threaded rack openings. The adapter removably couples an unthreaded support to the rear of a mounting portion of the rail aligned to enter an unthreaded opening of a rack. An end user removes the adapter to secure the rail to threaded rack openings and couples the adapter to secure the rail to unthreaded rack openings.

More specifically, an information handling system has plural chassis disposed in a rack, such as in a vertically stack arrangement. Each chassis includes a processor and memory interfaced through a circuit board, such as a server information handling system processing module. Each chassis couples to one or more rails which slidingly dispose each chassis in the rack interior for normal use and the rack exterior for maintenance or replacement. For instance, a pair of rails disposed on opposing side support members of the rack having a mounting portion coupled to the rack and a sliding portion that slides relative to the rack. The mounting portion has a mount with a front face that has one or more openings sized to accept a threaded screw that engages with threads of a threaded opening of the rack to couple the rail to the rack. An adapter couples to the mounting portion front face with a support secured from the rear of the mounting portion to the adapter through the rail opening. For example, the support screws onto a pin extending from the adapter and engages a beveled edge with the rail opening. The support has a size and shape that inserts into an unthreaded rack opening, such as a round shape or a square shape, and an attachment device that couples with the rack to hold the support in the rack opening. For instance, the attachment device is a latch that extends out the rear face of the mounting portion to engage in a rack opening and a release lever interfaced with the latch and disposed at the front face to allow access by an end user for ready removal of the rail with activation of the release lever to release the latch, thus allowing the support to slide out of the rack opening.

The present invention provides a number of important technical advantages. One example of an important technical advantage is that a rail attaches to both threaded and unthreaded openings of a rack. The rail without an adapter has openings that accept a standard pan head screw to allow direct attachment to a rack with the screws engaging a threaded opening. The rail with an adapter couples to unthreaded round or square openings of a rack using an attachment device accessible at the front of the rack and exposed for interaction by an end user. The adapter couples to the rail opening with a support engaging the adapter to the rail and an attachment device that holds the support in the rail by coupling the adapter to the rail. The adapter provides for direct support of thread-hole racks without an additional adapter and provides a more robust mounting structure capable of supporting heavier loads for unthreaded rack openings relative to existing adapters, with higher available vertical and torsional loads. In addition, the adapter is removable for replacement in the event of a failure or creeping over time without having to replace an entire rail.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an information handling system having a rack that holds plural chassis processing modules on sliding rails;

FIG. 2 depicts a rail mounting portion having an adapter coupled to its front face for tool-less coupling of the rail to the rack;

FIG. 3 depicts a blow-up view of the adapter aligned to couple to a rail mounting portion;

FIG. 4 depicts the rail with the adapter removed and having screws that couple the rail to threaded rack openings;

FIG. 5 depicts a rear view of the rail coupled with the adapter to a rack having round unthreaded openings; and

FIG. 6 depicts a rear view of the rail coupled with the adapter to a rack having square unthreaded openings.

### DETAILED DESCRIPTION

An information handling system slides on a rail coupled to a rack with a removably attached tool-less adapter for interacting with unthreaded rack openings. When the tool-less adapter is removed from the rail, openings of the rail provide a direct attachment by threaded screws to a rack having threaded openings. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

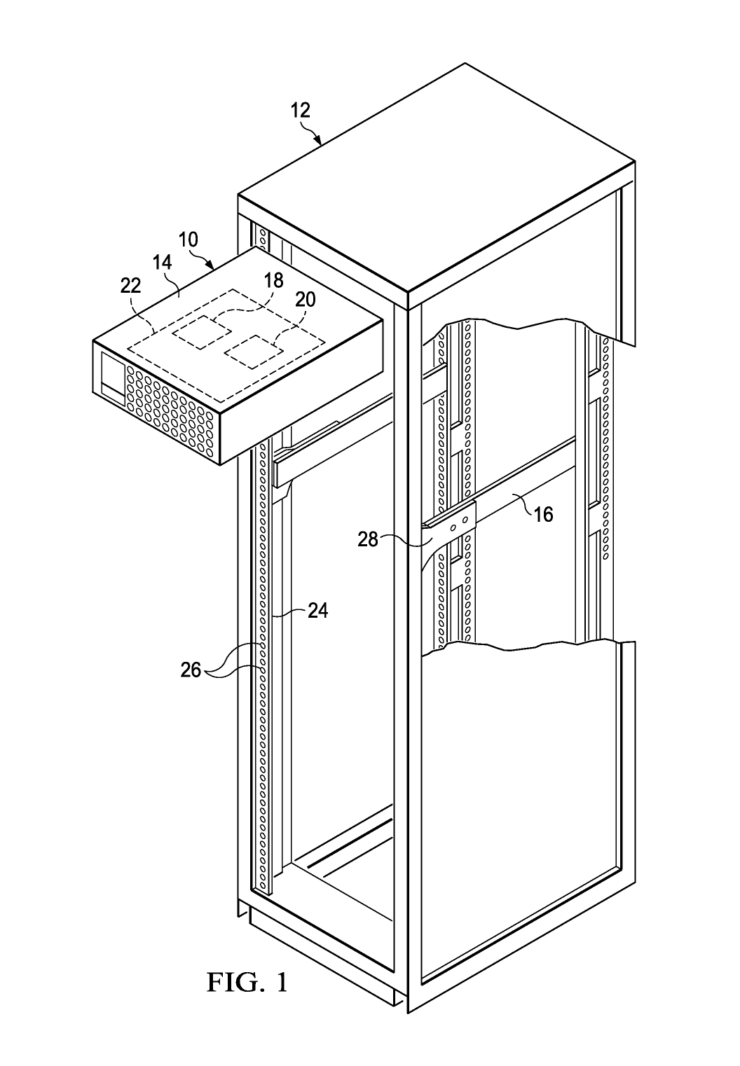

Referring now to FIG. 1, an information handling system 10 is depicted having a rack 12 that holds plural chassis processing modules 14 on sliding rails 16. For example, each chassis processing module 14 is a server information handling system module having a processor 18 and random access memory (RAM) 20 disposed on a circuit board 22. During information processing, a chassis 14 slides into the interior body of rack 12 on rails 16 disposed on opposing sides of rack 12. If maintenance or replacement of a chassis 14 is required, the chassis 14 is slid on opposing rails 16 out of the interior of rack 12 for access by an end user. In one example embodiment, rack 12 has standard dimensions that accept up to forty-four 1U chassis 14. In alternative embodiments, racks of various dimensions and orientations may be used.

Rack 12 has support members 24 vertically disposed along each corner and having plural vertically-disposed openings 26 to accept rails 16. For example, each support member 24 has three openings per 1U of height to couple with a mount 28 of rail 16. Openings 26 have standardized coupling options including a square unthreaded opening, a round unthreaded opening and a round threaded opening that accepts a screw. Mount 28 couples to one or more of the openings 26 to hold rail 16 in place. In alternative embodiments, alternative types of racks 12 with alternative types of openings 26 may be used.

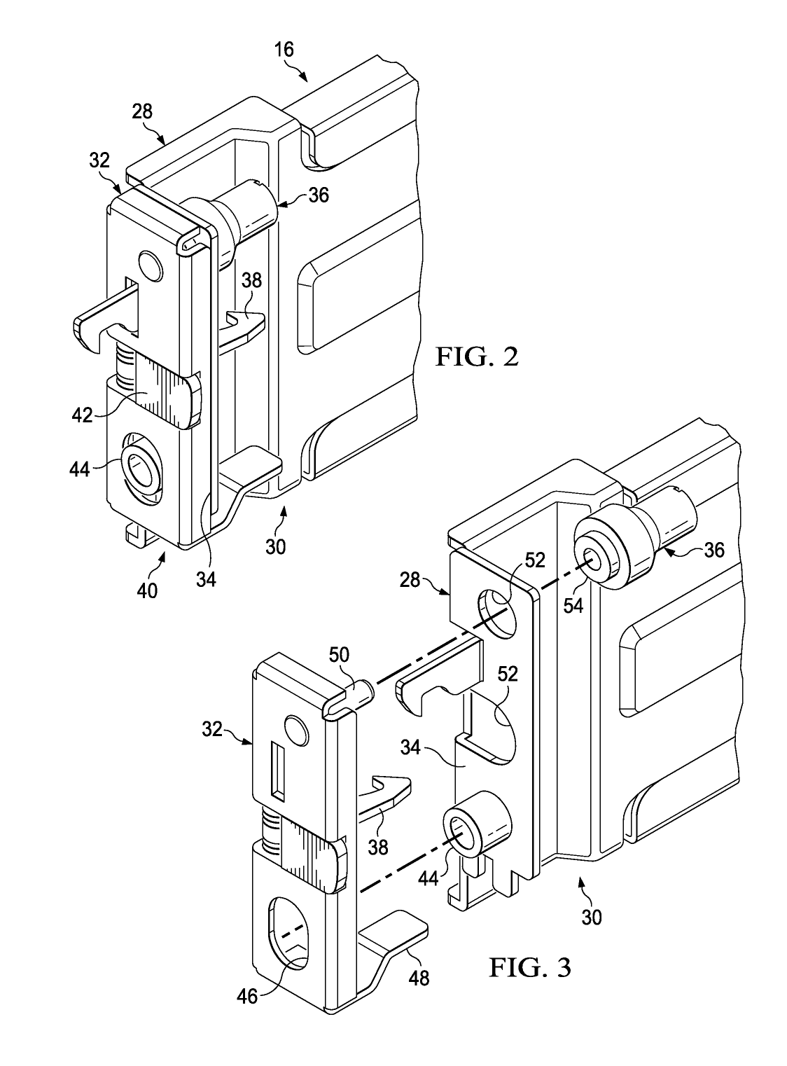

Referring now to FIG. 2, a rail mounting portion 30 is depicted having an adapter 32 coupled to its front face 34 for tool-less coupling of the rail 16 to the rack 12. Adapter 32 couples to the front face 34 of mount 28 and has a support 36 that extends out the rear of mount 34. Support 36 has a shape that engages an opening of rack 12 to support the weight of rail 16 inside of rack 12. In the depicted example, support 36 has a round shape with a smaller diameter at the end of its length sized to fit in a standard unthreaded round rack opening and with a greater diameter at the base of its length sized to fit in a standard unthreaded square rack opening. In alternative embodiments, support 36 has a diameter and shape for fitting into only one type of unthreaded rack opening, such as a round or square shape. As support 36 is pushed into a rack opening, a latch 38 aligns with and engages another rack opening to hold adapter 32 and thus attach mount 28 in place at the rack. Latch 38 is a part of an attachment device having a release lever 42 disposed at the front of adapter 32. Release lever 42 is accessible for an end user to grab and pull outward, translating a release force to latch 38 for disengaging latch 38 from rack 12. Once latch 38 is released from a rack opening, support 36 is free to slide out of its rack opening to release rail 16 from the rack. In the example embodiment, a guide 44 extending out from mount 28 aids in the aligning of adapter 32 into position over the front face 34 of mount 28.

Referring now to FIG. 3, a blow-up view depicts the adapter 32 aligned to couple to a rail mounting portion 30. Adapter 32 is formed, for example, from pressed and machined sheet metal to have a guide opening 46 that fits over guide 44 so that adapter 32 aligns into a desired position over the front face 34 of mount 28. A lip 48 engages the lower surface of mount 28 to secure adapter 32 in place over front face 34. A pin 50 extends out the rear of adapter 32 and through an opening 52 formed in mount 28, such as the opening otherwise used for insertion of threaded screws through mount 28 and into a threaded rack opening. Latch 38 extends out the rear of adapter 32 and through a second opening 52 of mount 28. When adapter 32 clips into position adjacent to and covering front face 34, then latch 38 and pin 50 are exposed at the rear face of mount 28. Support 36 has a beveled end 54 with a narrower diameter than opening 52 that snuggly fits to opening 52 when support 36 couples with pin 50. For example, support 36 screws onto threads formed in pin 50 or has an alternative coupling mechanism within its interior that selectively couples with pin 50. By securely coupling to pin 50 with beveled end 54 in opening 52, support 36 provides the dual roles of attaching adapter 32 to front face 34 and providing a peg to insert into a rack opening.

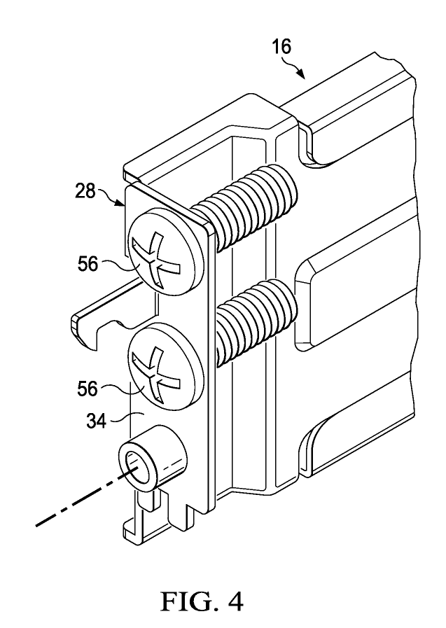

Referring now to FIG. 4, the rail 16 is depicted with the adapter 32 removed and having screws 56 that couple the rail 16 to threaded rack openings. With adapter 32 removed from front face 34 of mount 28, openings 52 formed in front face 34 accepted threaded screws 56 that engage threaded openings of a rack. Attaching rail 16 directly to a rack with screws 56 is accomplished when a rack has threaded openings that are not adapted to accept tool-less attachment of a rail. By removing adapter 32, attachment with screws 56 is accomplished without adding bulk to the assembly.

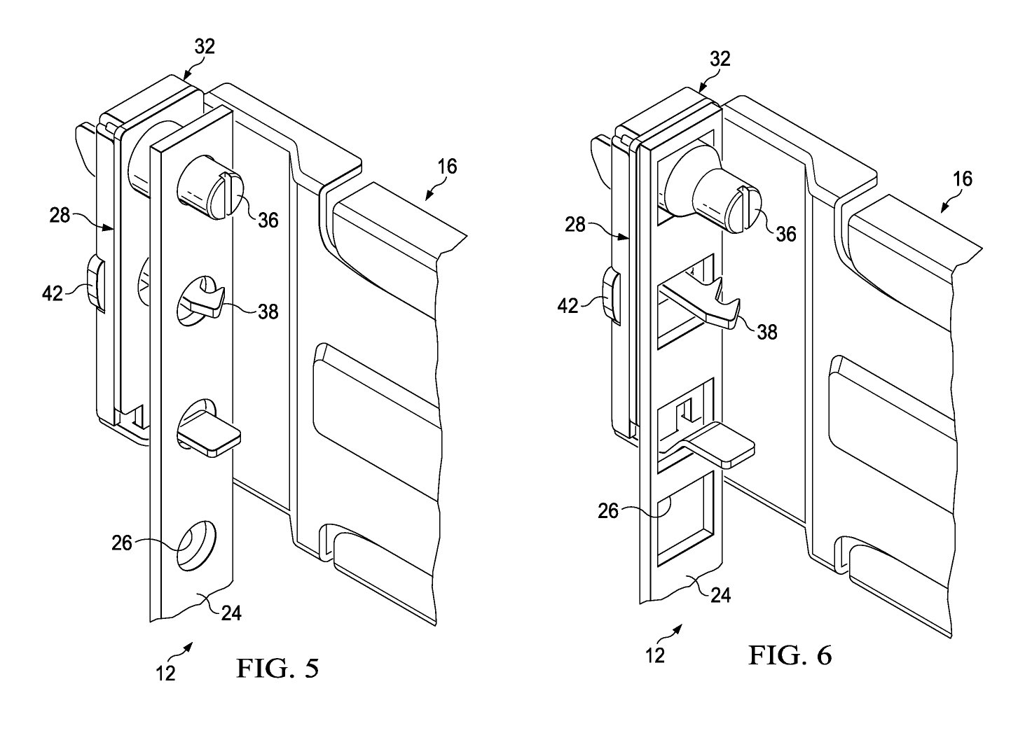

Referring now to FIG. 5, a rear view depicts the rail 16 coupled with the adapter 32 to a rack 12 having round unthreaded openings 26. Support 36 provides a peg that inserts into an opening 26 of a support member 24 to support the weight of rail 16. Latch 38 inserts into another opening 26 of support member 24 to prevent lateral movement of mount 28 and adapter 32 relative to rack support member 24 so that support 36 remains in place. If release lever 42 is actuated by pulling towards the front of rack 12, then latch 38 releases opening 26 to allow removal of support 36 from opening 26. As depicted by FIG. 5, the round portion of support 36 fits into the round unthreaded opening of support member 24 at a narrow diameter so that a larger diameter at the base of support 36 does not enter into opening 26. In an alternative embodiment support 36 has a round portion at its end and a square portion at its base so that the round portion enters into a round opening 26 until the square portion rests against the circumference of opening 26 without entering opening 26. In the embodiment depicted by FIG. 5, the lower opening 26 aligned with adapter 32 has a flat-shaped guide extending through it to aid in alignment.

Referring now to FIG. 6, a rear view depicts the rail 16 coupled with the adapter 32 to a rack 12 having square unthreaded openings 26. The round end portion of support 36 has a diameter smaller than the square opening 26 so that the round end portion of support 36 passes completely through opening 26 until the increased round diameter at the base of support 36 fills opening 26. Having one round shape with an increasing diameter at the base adapts support 36 to fit in round or square openings 26. The flat-shaped guide in the lower opening 26 slides or twists to engage the rack and help hold adapter 32 in place. In an alternative embodiment, a square portion of support 36 engages a square opening 26. An advantage of a completely round shape of support 26 is that the orientation of support 36 does not matter relative to square opening 26. In an alternative embodiment, support 36 has only a round shape with a gradually increasing diameter at the beveled end 54 so that support 36 will fill opening 26 of rack 12 support member 24 when support member 36 enters opening 26 far enough to engage the sides of opening 26 with support member 36's increasing diameter. This adapts support 36 to multiple-sized rack openings. In alternative embodiments, support member 36 has substantially only one shape and diameter designed to engage with the openings or a particular rack 12. For example, if an end user has a rack with round openings, the end user selects a round support member to couple with adapter 32. If an end user has a square shape, the end user selects a square support member to couple with adapter 32. In one alternative embodiment, support member 36 has a round shape and a square portion that fits over the round shape so that an end user attaches the square portion over the round portion when a rack with square openings is in use.

Although the present invention has been described in detail, it should be understood that various changes, substitutions and alterations can be made hereto without departing from the spirit and scope of the invention as defined by the appended claims.

What is claimed is:

1. An information handling system comprising:
a rack having plural openings;
a chassis having a circuit board, processor and memory operable to process information;
a rail operable to couple to the chassis to support the chassis in the rack, the rail having one or more openings disposed at a front face to align with one or more of the rack plural openings; and
an adapter operable to removably couple to the one or more rail openings over the front face, the adapter having a support that extends from the front face towards the rail, the support sized to fit into one of the rack plural openings, the adapter further having an attachment device operable to removably couple with the rack.

2. The information handling system of claim 1 wherein the adapter further comprises a pin operable to couple to an opening of the front face, the support removably coupling to the pin, the pin removable so that a screw can pass through the opening of the front face and into a threaded rack opening.

3. The information handling system of claim 2 wherein the support comprises a round peg having substantially only a round shape sized to fit in a round unthreaded rack opening.

4. The information handling system of claim 3 further comprising a square portion having an opening sized to fit over the round peg, the square portion sized to fit in a square unthreaded rack opening.

5. The information handling system of claim 2 wherein the support comprises a square peg having substantially only a square shape sized to fit in a square unthreaded rack opening.

6. The information handling system of claim 2 wherein the support comprises a peg having round portion sized to fit in a round unthreaded rack opening and a square portion sized to fit in a square unthreaded rack opening, the round portion smaller than the square portion so that the round portion passes through a square unthread rack opening to have the square portion engage with the square unthreaded rack opening.

7. The information handling system of claim 1 wherein the attachment device comprises a lever exposed at the front face of the rail and coupled with a latch operable to engage one of the plural openings of the rack.

8. The information handling system of claim 1 wherein the rail one or more openings are sized to accept a threaded screw when the adapter is removed from the front face, the threaded screw operable to engage a rack threaded opening.

9. A method for coupling a rail to a rack, the method comprising:
coupling an adapter to a front face of the rail, the adapter having a support shaped to fit in an opening of the rack, the support extending behind the front face of the rail and into the rack; and
coupling the adapter to the rack to hold the rail at the rack, the adapter coupled to the rack with an attachment device having an actuator at the front face of the rail and a latch extending behind the front face of the rail and into the rack.

10. The method of claim 9 wherein coupling an adapter further comprises:
disposing a pin of the adapter through the front face of the rail into an opening of the rail; and
attaching the support to the pin, the support attached from a rear face of the rail to couple the adapter to the rail.

11. The method of claim 9 wherein coupling the adapter to the rack further comprises inserting the support into an opening of the rack.

12. The method of claim 11 further comprising:
selecting a round support to couple to the pin if the rack has round openings to accept the support; and
selecting a square support to couple to the pin if the rack has square openings to accept the support.

13. The method of claim 9 further comprising:
removing the adapter from the front face of the rail to expose openings of the rail; and
coupling the rail to a rack with a screw through the openings of the rail.

14. A rail comprising:
a mounting portion having a front face with plural openings;
a sliding portion interfaced with the mounting portion and operable to slide between plural positions;
an adapter having a support and an attachment device, the adapter operable to removably couple to the front face and to a rack to hold the mounting portion to the rack.

15. The rail of claim 14 wherein the support couples the adapter to the mounting portion by securing to a pin of the adapter, the pin extending from the adapter at the front face through one of the plural openings.

16. The rail of claim 15 further comprising a bevel formed on the support and sized to fit into the one of the plural openings around the pin.

17. The rail of claim 14 wherein the front face plural openings are sized to accept a threaded screw, the rail further comprising a threaded screw operable to fit through one of the front face threaded openings to engage a threaded opening of a rack when the adapter is removed from the mounting portion.

18. The rail of claim 14 wherein the support comprises a round peg having substantially only a round shape for insertion into a rack unthreaded round opening.

19. The rail of claim 14 wherein the support comprises a square peg having substantially only a square shape for insertion into a rack unthreaded square opening.

20. The rail of claim 14 wherein the support comprises a round shape having a first diameter at an end that transitions to a second larger diameter at a base, the first diameter sized to fit into a round unthreaded rack opening, the second diameter sized to fit into a square unthreaded rack opening.
